(19) United States
(12) Patent Application Publication
(10) Pub. No.: US 2018/0297441 A1
(43) Pub. Date: Oct. 18, 2018

(54) RECREATIONAL VEHICLE AIR CONDITIONING TESTER

(71) Applicant: Gregory Rosado, Lansing, MI (US)

(72) Inventor: Gregory Rosado, Lansing, MI (US)

(21) Appl. No.: 15/486,934

(22) Filed: Apr. 13, 2017

(51) Int. Cl. B60H 1/00; F25B 49/02; G01R 19/145

(52) U.S. Cl. CPC B60H 1/00585; F25B 49/02; G01R 1/0416; H01R 2201/26; G01R 19/145

(57) ABSTRACT

A portable recreational vehicle air conditioning tester that allows a user to test an air conditioning unit without removing the air conditioning unit from the recreational vehicle while providing independent power supply and positive control.

### FIELD OF THE INVENTION

This invention relates to an apparatus that can diagnose recreational vehicle air conditioners. More particularly, air conditioners in recreational vehicles.

### BACKGROUND OF THE INVENTION

To test or monitor the features or conditions, such as volts or amperes, in an air conditioning unit installed in, or on a recreational vehicle sometimes involves removing the air conditioning unit from the roof of the recreational vehicle. Also requires the rest of the heating/cooling wiring to work perfectly.

The typical recreational unit air conditioning unit weighs about eighty five (85) pounds. So to remove and replace the air conditioning unit for testing is physically demanding and time consuming.

There exists a need for a portable device that can test and diagnose an air conditioning unit on a recreational vehicle, or wherever air conditioning units are located in inconvenient locations.

There also exists a need for a portable device that is controllable and has an independent power source.

There exists a need to test and diagnose recreational vehicle air conditioners by plugging the air conditioner male plug into a plug of a handheld device.

Multiple embodiments of the system are disclosed herein. It will be understood that other objects and purposes of the invention, and variations thereof, will be apparent upon reading the following specification and inspecting the accompanying drawings.

### SUMMARY OF THE INVENTION

One aspect of the present invention is an recreational vehicle air conditioning tester, comprising: a recreational vehicle female plug; at least one of either an on/off compressor switch or an off/low/hi fan switch operably connected to said recreational vehicle female plug; at least one of either, or an amperage display is operably connected to said recreational vehicle female plug; and at least one of either said voltage display or said amperage display is operably connected to at least one of either said on/off compressor switch or said off/low/hi fan switch whereby at least one of either said voltage display or said amperage display is activated when either said on/off compressor switch or said off/low/hi fan switch is on, and the recreational vehicle air conditioning tester is operably connected to a power supply, and said recreational vehicle female plug is connected to an air conditioning male plug.

These and other features, aspects and advantages of the present invention will become better understood with reference to the following drawings, description and claims.

### BRIEF DESCRIPTION OF THE DRAWINGS

FIG. 1 is a pictorial view of one embodiment of the present invention connected to an air conditioning unit;

FIG. 2 is a pictorial view of an embodiment of the present invention not connected to an air conditioning unit;

FIG. 3 is a schematic view of the circuitry of an embodiment of the present invention; and

FIG. 4 is a different schematic view of the circuitry of another embodiment of the present invention

### DETAILED DESCRIPTION OF THE INVENTION

### Reference Numerals

10 recreational vehicle air conditioning tester
20 six pin plug
30 nine pin plug
40 on/off compressor switch
50 off/low/hi fan switch
60 voltage display
70 amperage display
80 power cord
90 electrical harness from air conditioning unit
100 ground wire
110 common wire
120 internal on/off compressor switch
130 internal off/low/hi fan switch
140 air conditioning male plug
150 indicator light
152 hi fan indicator light
154 low fan indicator light
156 compressor indicator light
160 indicator light plug
170 recreational vehicle female plug
180 air conditioning unit

The following detailed description is of the best currently contemplated modes of carrying out the invention. The description is not to be taken in a limiting sense, but is made merely for the purpose of illustrating the general principles of the invention, since the scope of the invention is best defined by the appended claims.

Certain terminology will be used in the following description for convenience and reference only, and will not be limiting. For example, the words “upwardly,” “downwardly,” “rightwardly,” and “leftwardly” will refer to directions in the drawings to which reference is made. The words “inwardly” and “outwardly” will refer to directions toward and away from, respectively, the geometric center of the system and designated parts. Said terminology will include the words specifically mentioned, derivatives, and similar words. Also, “connected to,” “secured to,” or similar language includes the definitions “indirectly connected to,” “directly connected to,” “indirectly secured to,” and “directly secured to.”

FIG. 1 discloses one embodiment of the present invention 10, which may be referred to as a recreational vehicle air conditioning tester 10. It may have a recreational vehicle female plug 170, such as a six pin plug 20 for compatibility with certain recreational vehicle air conditioning male plugs 140, also referred to as harnesses 140, such as many Dematic® or an Advent® unit.

The recreational vehicle female plug 170 may also be a nine pin plug 30 for use with other types of air conditioning male plugs 140 or harnesses 140, such as some made by Coleman® company.

FIG. 1 shows the air conditioning unit 180, with the wire harness 140, also referred to as the air conditioning male plug 170 extending down from the air conditioning unit 180.

In fact, any type of female pin plug may be utilized with the present invention.

In one embodiment of the present invention 10, a power cord 80 may be operably connected thereto. When the power cord 80 is plugged into a power source, then the present invention 10 may have power to be activated.

In one embodiment, the six pin plug 20 may be operably connected to at least one of either an off/low/hi fan switch 50 or an on/off compressor switch 40. At least one of either the off/low/hi fan switch 50 or the on/off compressor switch 40 may be operably connected to at least one of either a voltage display 60 or an amperage display 70. The power cord 80 may be operably connected to at least one of either the on/off compressor switch 40 and the off/low/hi fan switch 50. The power cord 80 may be operably connected to at least one of either the voltage display 60 or the amperage display 70.

After the male plug 140 is plugged into the appropriate female plug, and after the present invention 10 is plugged in to a power source, such as a standard outlet, then the on/off compressor switch 40 or the off/low/hi fan switch 50 can be activated to display the voltage via a voltage display 60, or to display the amps via an amperage display 70.

Both the compressor switch 40 and the off/low/hi fan switch 50 may be on at the same time and the compressor and fan will be on, and the device 10 will provide a total amp draw.

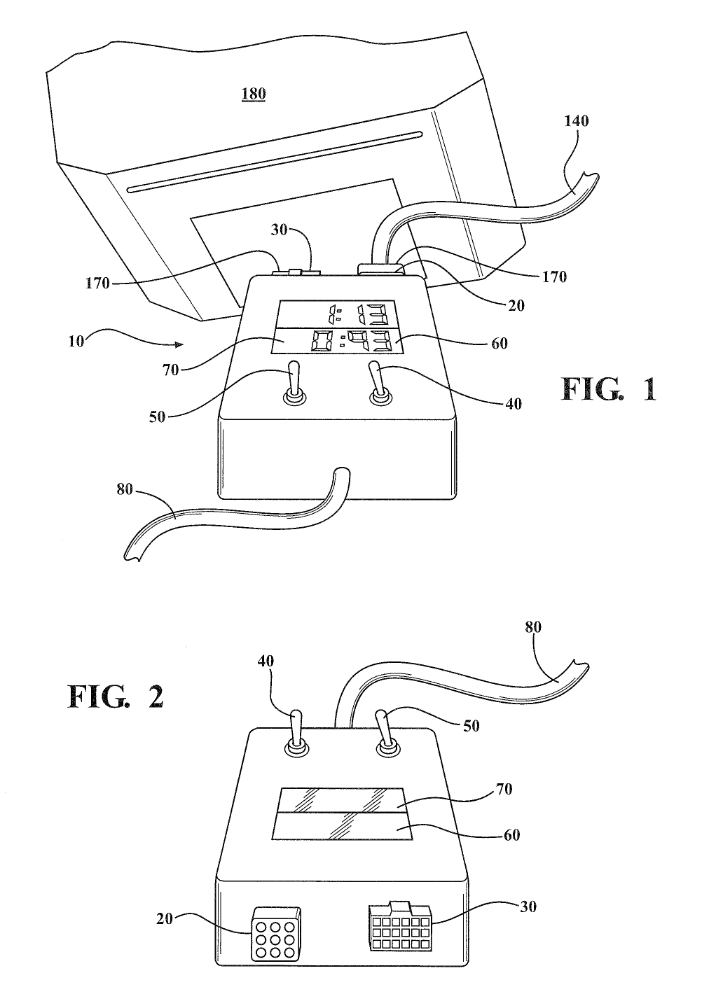

FIG. 2 illustrates an embodiment of the present invention. Both the six pin plug 20 and nine pin plug 30 are illustrated as disposed on one side. Both the on/off compressor switch 40 and the off/low/hi fan switch 50 may be disposed on the top side. And both the voltage display 60 and amperage display 70 may be on the top side. The power cord 80 is illustrated as extending from the side opposite of the six pin plug 20 and nine pin plug 30. The aforementioned components may be arranged in any configuration.

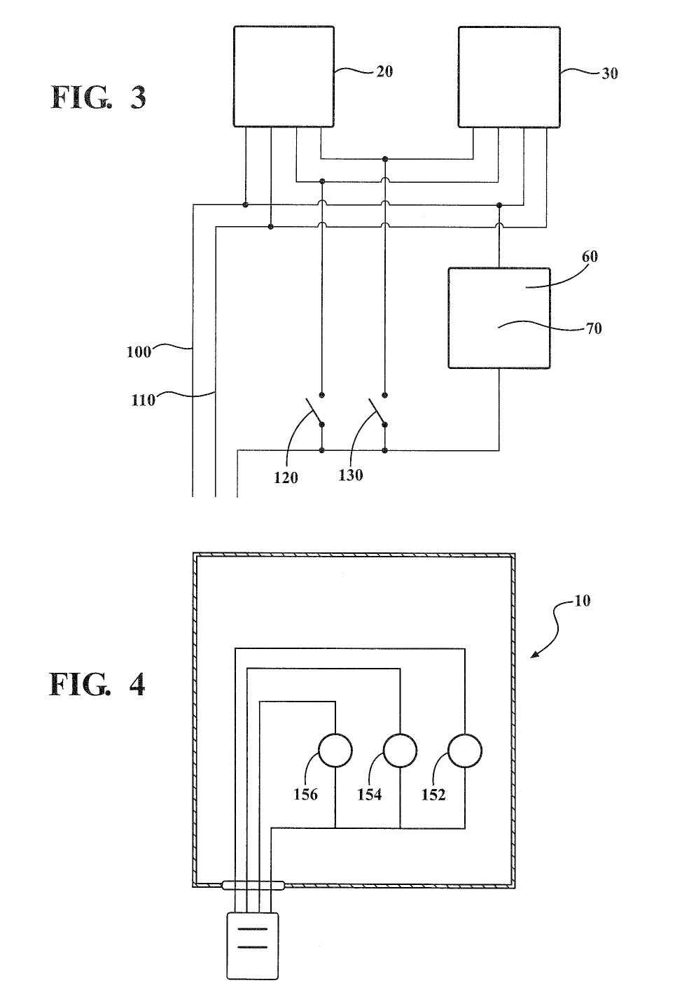

FIG. 3 illustrates one embodiment of a schematic view of the present invention 10.

FIG. 3 illustrates how the six pin plug 20 may be operably connected to both the on/off compressor switch 40 and the off/low/hi switch 50. It also shows how the six pin plug 20 may be connected to at least one of either the voltage display 60 or the amperage display 70. In one embodiment the voltage display 60 and amperage display 70 is one single unit.

The power cord 80 is illustrated in FIG. 3 as having a ground, hot, and neutral plug for a standard three pronged power cord 80. However, in another embodiment, the power cord 80 may have a two-pronged plug,

FIG. 4 illustrates another embodiment of the present invention 10, having indicator lights 150 to test other conditioning components. The present invention can be used to test the junction box. The indicator lights may inform the user if everything upstream of the air conditioner roof unit is working properly, by informing the user if the roof unit is receiving a signal to turn on. The indicator light 150 may be operably connected to an indicator light plug 160. Thin indicator light plug 150 may be the same as the air conditioning male plug 140 and the same as the recreational vehicle female plug 170.

In one embodiment there may be a hi fan indicator light 153, which may be red; there may be a low fan indicator light 154, which may be green; and there may be a compressor indicator light 156, which may be blue.

It should be understood, of course, that the foregoing relates to exemplary embodiments of the invention and that modifications may be made without departing from the spirit and scope of the invention as set forth in the following claims.

I claim:

1. Recreational vehicle air conditioning tester (10), comprising:
a recreational vehicle female plug (170);
at least one of either an on/off compressor switch (40) or an off/low/hi fan switch (50) operably connected to said recreational vehicle female plug (170);
at least one of either a voltage display (60), or an amperage display (70) is operably connected to said recreational vehicle female plug (170); and
at least one of either said voltage display (60) or said amperage display (70) is operably connected to at least one of either said on/off compressor switch (40) or said off/low/hi fan switch (50);
whereby at least one of either said voltage display (60) or said amperage display (70) is activated when either said on/off compressor switch (40) or said off/low/hi fan switch (50) is on, and the recreational vehicle air conditioning tester (10) is operably connected to a power supply, and said recreational vehicle female plug (170) is connected to an air conditioning male plug (140).

2. The apparatus of claim 1, further comprising at least one indicator light (150) operably connected to at least one of either a six pin plug (20) or a nine pin plug (30);
whereby said indicator light is activated when a certain condition is present on the air conditioning unit (180).
